(19) United States
(12) Patent Application Publication
(10) Pub. No.: US 2018/0102238 A1
(43) Pub. Date: Apr. 12, 2018

(54) SUBSTRATE SUPPORT UNIT, SUBSTRATE TREATING APPARATUS INCLUDING THE SAME, AND METHOD FOR CONTROLLING THE SAME

(71) Applicant: SEMES CO., LTD., Chungcheongnam-do (KR)

(72) Inventors: Jamyung GU, Chungcheongnam-do (KR); Jong Hwan AN, Gyeonggi-do (KR); Shin-Woo NAM, Gyeonggi-do (KR); Sooryun RO, Suwon-si (KR)

(73) Assignee: SEMES CO., LTD., Chungcheongnam-do (KR)

(21) Appl. No.: 15/702,119

(22) Filed: Sep. 12, 2017

(30) Foreign Application Priority Data
Oct. 6, 2016 (KR) 10-2016-0128974

(51) Int. Cl. H01J 37/32; H02N 13/00; H03H 7/38; H01L 21/67; H01L 21/683

(52) U.S. Cl. CPC H01J 37/32642; H02N 13/00; H03H 7/38; H01L 21/67069; H01L 21/6831; H01J 2237/0203; H01J 37/32174; H01J 37/32477; H01J 37/32715; H01J 37/32522; H01J 2237/334; H01J 37/32449

(57) ABSTRACT

A substrate treating apparatus includes a chamber having a treatment space in the interior thereof, a support unit that supports a substrate in the treatment space, a gas supply unit configured to supply a treatment gas into the treatment space, and a plasma source configured to generate plasma from the treatment gas. The support unit includes an electrostatic chuck, on which the substrate is positioned, a first ring surrounding a circumference of the substrate positioned on the electrostatic chuck, a second ring surrounding a circumference of the electrostatic chuck and formed of an insulation material, an insertion body disposed in the second ring and formed of a conductive material, and an impedance control unit configured to adjust an impedance of the insertion body.

### CROSS-REFERENCE TO RELATED APPLICATIONS

A claim for priority under 35 U.S.C. § 119 is made to Korean Patent Application No. 10-2016-0128974 filed on Oct. 6, 2016, in the Korean Intellectual Property Office, the entire contents of which are hereby incorporated by reference.

### BACKGROUND

Embodiments of the inventive concept described herein relate to a substrate support unit, a substrate treating apparatus including the same, and a method for controlling the same.

A semiconductor manufacturing process may comprise a process of treating a substrate by using plasma. For example, in an etching process of the semiconductor process, a thin film on the substrate may be removed by using plasma.

In a substrate treating process, such as an etching process using plasma, a plasma area has to be expanded to a peripheral area of the substrate to increase the process uniformity to the periphery of the substrate. To achieve this, a ring member that may exhibit an electric field coupling is provided to surround a substrate support member, and for example a ring-shaped insulator is used as the ring member to electrically isolate from a lower module of the equipment.

However, as the operation time of the etching equipment increases, an upper surface of the above-mentioned ring member, which is exposed to plasma, is worn out by ions accelerated by a plasma sheath. The worn ring member influences an etching profile of a periphery of the substrate, and accordingly, it has to be periodically replaced.

### SUMMARY

An objective of the inventive concept is to easily control an electric field of a periphery of a substrate in a substrate treating apparatus that performs a plasma process.

Another objective of the inventive concept is to extend an exchange cycle by reducing a degree by which a ring member provided at a circumference of a substrate support is worn.

Another objective of the inventive concept is to increase the uniformity of plasma formed in a peripheral area of a substrate by controlling an impedance of an insertion body inserted into a ring member.

The objects of the inventive concept are not limited to the above-described ones. Other technical objects that are not mentioned will be clearly understood from the following description by those skilled in the art to which the inventive concept pertains.

In accordance with an aspect of the inventive concept, there is provided a substrate treating apparatus comprising a chamber having a treatment space in the interior thereof, a support unit that supports a substrate in the treatment space, a gas supply unit configured to supply a treatment gas into the treatment space, and a plasma source configured to generate plasma from the treatment gas;

The support unit may comprise an electrostatic chuck, on which the substrate is positioned, a first ring surrounding a circumference of the substrate positioned on the electrostatic chuck, a second ring surrounding a circumference of the electrostatic chuck and formed of an insulation material, an insertion body disposed in the second ring and formed of a conductive material, and an impedance control unit configured to adjust an impedance of the insertion body.

The support unit further comprise a high frequency power source configured to provide RF power to an electrode provided in the electrostatic chuck, and the impedance control unit may control coupling between the electrostatic chuck and the first ring by adjusting an impedance of the insertion body.

The impedance control unit may comprise an inductor and a variable capacitor.

The inductor and the variable capacitor may be connected to each other in series or in parallel.

The insertion body may be formed of a metallic material.

The insertion body may be formed of a dielectric material.

The second ring may be disposed below the first ring.

An upper end of a central area of the electrostatic chuck may be higher than an upper end of a peripheral area of the electrostatic chuck.

An upper end of the first ring may be higher than the upper end of the central area of the electrostatic chuck, a lower end of the first ring may be lower than the upper end of the central area, and a portion of the first ring may be located above the peripheral area of the electrostatic chuck.

An upper end of the second ring may be located at a height that is the same as or lower than the upper end of the peripheral area of the electrostatic chuck.

A third ring of a metallic material may be provided between the first ring and the second ring.

In accordance with another aspect of the inventive concept, there is provided a substrate support unit for supporting a substrate in a plasma process chamber, the substrate support unit comprising an electrostatic chuck, on which the substrate is positioned, a first ring surrounding a circumference of the substrate positioned on the electrostatic chuck, a second ring surrounding a circumference of the electrostatic chuck and formed of an insulation material, an insertion body disposed in the second ring and formed of a conductive material, and an impedance control unit configured to adjust an impedance of the insertion body.

The substrate support unit may further comprise a high frequency power source configured to provide RF power to an electrode provided in the electrostatic chuck.

The impedance control unit may control coupling between the electrostatic chuck and the first ring by adjusting an impedance of the insertion body.

The impedance control unit may comprise an inductor and a variable capacitor.

The inductor and the variable capacitor may be connected to each other in series or in parallel.

The insertion body may be formed of a metallic material.

The insertion body may be formed of a metallic material.

The second ring may be disposed below the first ring.

An upper end of a central area of the electrostatic chuck may be higher than an upper end of a peripheral area of the electrostatic chuck.

An upper end of the first ring may be higher than the upper end of the central area of the electrostatic chuck, a lower end of the first ring may be lower than the upper end of the central area, and a portion of the first ring may be located above the peripheral area of the electrostatic chuck.

An upper end of the second ring may be located at a height that is the same as or lower than the upper end of the peripheral area of the electrostatic chuck.

A third ring of a metallic material may be provided between the first ring and the second ring.

In accordance with another aspect of the inventive concept, there is provided a method for controlling a substrate treating apparatus, the method comprising generating coupling between an electrode provided in the electrostatic chuck and the insertion body by providing RF power to the electrode, and controlling an impedance of the insertion body by adjusting an element value of the variable capacitor.

The controlling of the impedance of the insertion body may comprise when a first substrate is treated and then a second substrate is treated, differently controlling an impedance of the insertion body during the treatment of the first substrate and an impedance of the insertion body during the treatment of the second substrate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is an exemplary view illustrating a substrate treating apparatus according to an embodiment of the inventive concept;

FIG. 2 is an exemplary sectional view of a substrate support unit according to an embodiment of the inventive concept;

FIGS. 3A and 3B are exemplary circuit diagram of a circuit included in an impedance control unit of FIG. 2;

FIGS. 4A and 4B are exemplary circuit diagrams for explaining an operation of an impedance control unit according to an embodiment of the inventive concept;

FIG. 5 is an exemplary flowchart illustrating a method for controlling a substrate treating apparatus according to an embodiment of the inventive concept; and

FIG. 6 is an exemplary flowchart illustrating a method for controlling a substrate treating apparatus according to an embodiment of the inventive concept.

### DETAILED DESCRIPTION

The above and other aspects, features and advantages of the invention will become apparent from the following description of the following embodiments given in conjunction with the accompanying drawings. However, the inventive concept is not limited to the embodiments disclosed below, but may be implemented in various forms. The embodiments of the inventive concept is provided to make the disclosure of the inventive concept complete and fully inform those skilled in the art to which the inventive concept pertains of the scope of the inventive concept.

Although not defined, all the terms (including technical or scientific terms) used herein may have the same meanings that are generally accepted by the common technologies in the field to which the inventive concept pertains. The terms defined by the general dictionaries may be construed to having the same meanings as those meant in the related technologies and/or the disclosure of the application, and will neither become conceptual nor be construed to be excessively formal even though not clearly defined herein.

The terms used herein are provided to describe the embodiments but not to limit the inventive concept. In the specification, the singular forms comprise plural forms unless particularly mentioned. The expressions ‘comprise’, ‘include’, and/or its various conjugated forms, such as ‘comprising’, ‘having’, ‘including’, which are used in the specification do not exclude existence or addition of one or more compositions, substances, elements, steps, operations, and/or devices. In the specification, the term ‘and/or’ represents enumerated configurations or various combinations thereof.

An objective of the inventive concept is to extend an exchange cycle of a focus ring, which is exposed to plasma to be worn, of a ring member surrounding a circumference of an electrostatic chuck configured to support a substrate in a substrate treating apparatus. According to an embodiment of the inventive concept, a change of an electric field of a periphery of the electrostatic chuck may be controlled through a circuit configured to control an impedance of a conductive material by mounting the conductive material that may induce an electric field coupling effect on the ring member. Accordingly, ions generated at an upper portion of the focus ring and passing through a plasma sheath may be controlled.

Hereinafter, exemplary embodiments of the inventive concept will be described in detail with reference to the accompanying drawings.

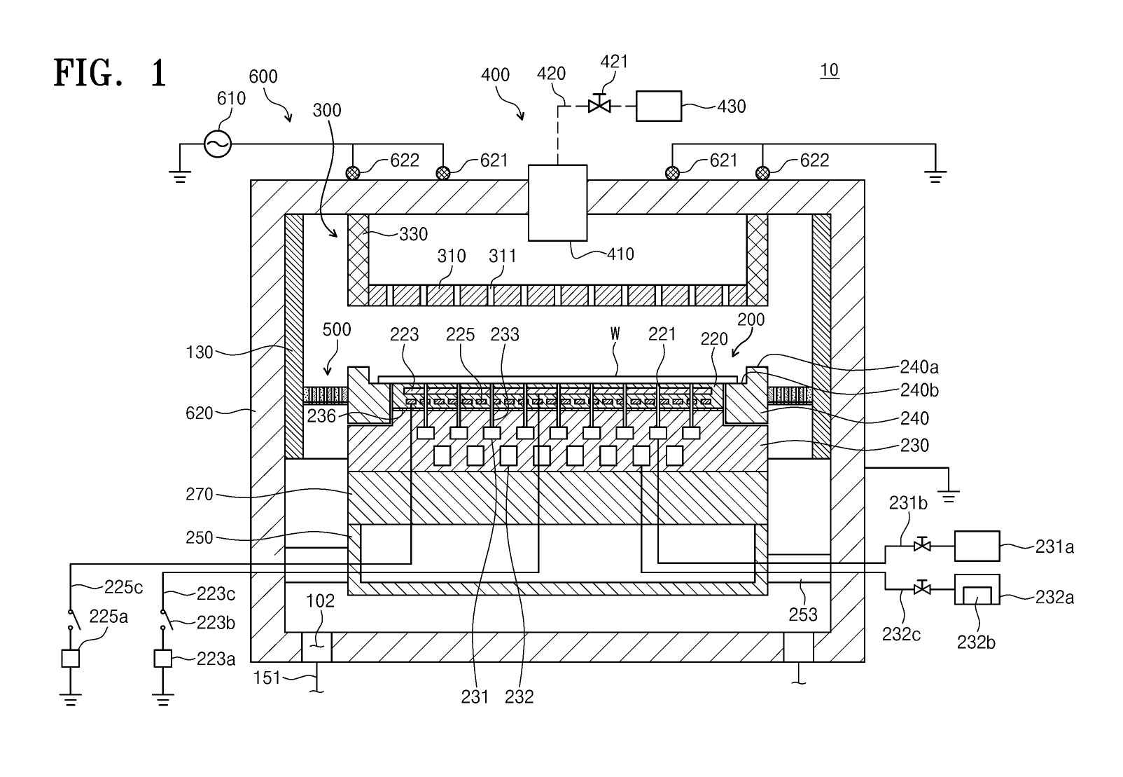

FIG. 1 is an exemplary view illustrating a substrate treating apparatus according to an embodiment of the inventive concept.

Referring to FIG. 1, the substrate treating apparatus 10 treats a substrate W by using plasma. For example, the substrate treating apparatus 10 may perform an etching process on the substrate W. The substrate treating apparatus 10 may comprise a chamber 620, a substrate support assembly 200, a shower head 300, a gas supply unit 400, a baffle unit 500, and a plasma generating unit 600.

The chamber 620 may provide a treatment space in which a substrate treating process is performed in the interior thereof. The chamber 620 may have a treatment space in the interior thereof, and may have a closed shape. The chamber 620 may be formed of a metallic material. The chamber 620 may be formed of aluminum. The chamber 620 may be grounded. An exhaust hole 102 may be formed on a bottom surface of the chamber 620. The exhaust hole 102 may be connected to an exhaust line 151. The reaction side-products generated in the process and gases left in the interior space of the chamber may be discharged to the outside through the exhaust line 151. The pressure of the interior of the chamber 620 may be reduced to a specific pressure through an exhaustion process.

According to an embodiment, a liner 130 may be provided in the interior of the chamber 620. Upper and lower surfaces of the liner 130 may have an opened cylindrical shape. The liner 130 may be provided to contact an inner surface of the chamber 620. The liner 130 may prevent an inner wall of the chamber 620 from being damaged due to arc discharging by protecting the inner wall of the chamber 620. Further, the liner 130 may prevent the impurities generated during the substrate treating process from being deposited to the inner wall of the chamber 620. Selectively, the liner 130 may not be provided.

A substrate support assembly 200 may be located in the interior of the chamber 620. The substrate support assembly 200 may support the substrate W. The substrate support assembly 200 may comprise an electrostatic chuck 210 configured to suction the substrate W by using an electrostatic force. Unlike this, the substrate support assembly 200 may support the substrate W in various methods such as mechanical clamping. Hereinafter, the substrate support assembly 200 including the electrostatic chuck 210 will be described.

The substrate support assembly 200 may comprise an electrostatic chuck 210, a lower cover 250, and a plate 270. The substrate support assembly 200 may be located in the interior of the chamber 620 to be spaced upwards apart from the bottom surface of the chamber 620.

The electrostatic chuck 210 may comprise a dielectric plate 220, a body 230, and a ring member 240. The electrostatic chuck 210 may support the substrate W. The dielectric plate 220 may be located at an upper end of the electrostatic chuck 210. The dielectric plate 220 may be formed of a dielectric substance of a disk shape. The substrate W may be positioned on an upper surface of the dielectric plate 220. The upper surface of the dielectric plate 220 may have a radius that is smaller than that of the substrate W. Accordingly, a peripheral area of the substrate W may be located on an outer side of the dielectric plate 220.

A first electrode 223, a heating unit 225, and a first supply passage 221 may be included in the interior of the dielectric plate 220. The first supply passage 221 may extend from an upper surface to a bottom surface of the dielectric plate 210. A plurality of first supply passages 221 are formed to be spaced apart from each other to be provided as passages through which a heat transfer medium is supplied to the bottom surface of the substrate W.

The first electrode 223 may be electrically connected to a first power source 223a. The first power source 223a may comprise a DC power source. A switch 223b may be installed between the first electrode 223 and the first power source 223a. The first electrode 223 may be electrically connected to the first power source 223a by switching on and off the switch 223b. If the switch 223b is switched on, a DC current may be applied to the first electrode 223. An electrostatic force may be applied between the first electrode 223 and the substrate W by a current applied to the first electrode 223, and the substrate W may be suctioned to the dielectric plate 220 by an electrostatic force.

The heating unit 225 may be located under the first electrode 223. The heating unit 225 may be electrically connected to a second power source 225a. The heating unit 225 may generate heat by a resistance due to a current applied to the second power source 225a. The generated heat may be transferred to the substrate W through the dielectric plate 220. The substrate W may be maintained at a specific temperature by the heat generated by the heating unit 225. The heating unit 225 may comprise a spiral coil.

The body 230 may be located under the dielectric plate 220. A bottom surface of the dielectric plate 220 and an upper surface of the body 230 may be bonded to each other by an adhesive 236. The body 230 may be formed of aluminum. An upper surface of the body 230 may be located such that a central area thereof is higher than a peripheral area thereof. The central area of the upper surface of the body 230 may have an area corresponding to a bottom surface of the dielectric plate 220, and may be bonded to the bottom surface of the dielectric plate 220. The body 230 may have first circulation passages 231, second circulation passages 232, and second supply passages 233 in the interior thereof.

The first circulation passages 231 may be provided as passages through which a heat transfer medium circulates. The first circulation passages 231 may be formed in the interior of the body 230 to have spiral shapes. Further, the first circulation passages 231 may be disposed such that passages having ring shapes of different radii have the same center. The first circulation passages 231 may communicate with each other. The first circulation passages 231 may be formed at the same height.

The second circulation passages 232 may be provided as passages through which a cooling fluid circulates. The second circulation passages 232 may be formed in the interior of the body 230 to have a spiral shape. Further, the second circulation passages 232 may be disposed such that passages having ring shapes of different radii have the same center. The second circulation passages 232 may communicate with each other. The second circulation passages 232 may have a sectional area that is larger than that of the first circulation passage 231. The second circulation passages 232 may be formed at the same height. The second circulation passages 232 may be located under the first circulation passages 231.

The second supply passages 233 may extend upwards from the first circulation passages 231, and may be provided on an upper surface of the body 230. The number of the second supply passages 243 corresponds to the first supply passages 221 and may connect the first circulation passages 231 and the first supply passages 221.

The first circulation passages 231 may be connected to a heat transfer medium storage 231a through heat transfer medium supply lines 231b. A heat transfer medium may be stored in the heat transfer medium storage 231a. The heat transfer medium may comprise an inert gas. According to an embodiment, the heat transfer medium may comprise a helium (He) gas. The helium gas may be supplied to the first circulation passages 231 through supply lines 231b, and may be supplied to the bottom surface of the substrate W after sequentially passing through the second supply passages 233 and the first supply passages 221. The helium gas may function as a medium by which the heat transferred from plasma to the substrate W is transferred to the electrostatic chuck 210.

The second circulation passages 232 may be connected to the cooling fluid storage 232a through the cooling fluid supply lines 232c. The cooling fluid storage 232a may store a cooling fluid. A cooler 232b may be provided in the cooling fluid storage 232a. The cooler 232b may cool the cooling fluid to a specific temperature. Unlike this, the cooler 232b may be installed on the cooling fluid supply line 232c. The cooling fluid supplied to the second circulation passages 232 through the cooling fluid supply lines 232c may cool the body 230 while circulating along the second circulation passages 232. The body 230 may cool the dielectric plate 220 and the substrate W together while being cooled to maintain the substrate W at a specific temperature.

The body 230 may comprise a metal plate. According to an embodiment, the whole body 230 may be formed of a metal plate.

The ring member 240 may be disposed at a peripheral area of the electrostatic chuck 210. The ring member 40 may have a ring shape and may be disposed along a circumference of the dielectric plate 220. An upper surface of the ring member 240 may be located such that an outer side 240a thereof is higher than an inner side 240b thereof. The inner side 240b of the upper surface of the ring member 240 may be located at the same height as that of the upper surface of the dielectric plate 220. The inner side 240b of the upper surface of the ring member 240 may support a peripheral area of the substrate W located on an outside of the dielectric plate 220. The outside 240a of the ring member 240 may be provided to surround a peripheral area of the substrate W. The ring member 240 may control an electromagnetic field such that densities of plasma are uniformly distributed in the whole area of the substrate W. Accordingly, plasma is uniformly formed over the whole area of the substrate W such that the areas of the substrate W may be uniformly etched.

The lower cover 250 may be located at a lower end of the substrate support assembly 200. The lower cover 250 may be spaced upwards apart from the bottom surface of the chamber 620. An open-topped space 255 may be formed in the interior of the lower cover 250. The outer radius of the lower cover 250 may have the same as the outer radius of the body 230. A lift pin module (not illustrated) that moves the transferred substrate W from a transfer member on the outside to the electrostatic chuck 210 may be located in the interior space 255 of the lower cover 250. The lift pin module (not illustrated) may be spaced apart from the lower cover 250 by a specific interval. A bottom surface of the lower cover 250 may be formed of a metallic material. The interior space 255 of the lower cover 250 may be provided with air. Because the dielectric constant of air is lower than that of an insulator, the air may reduce an electromagnetic field in the interior of the substrate support assembly 200.

The lower cover 250 may have a connecting member 253. The connecting member 253 may connect an outer surface of the lower cover 250 and an inner wall of the chamber 620. A plurality of connecting members 253 may be provided on an outer surface of the lower cover 250 at a specific interval. The connecting member 253 may support the substrate support assembly 200 in the interior of the chamber 620. Further, the connecting member 253 may be connected to the inner wall of the chamber 620 such that the lower cover 250 is electrically grounded. A first power line 223c connected to the first power source 223a, a second power line 225c connected to the second power source 225a, a heat transfer medium supply line 231b connected to the heat transfer medium storage 231a, and a cooling fluid supply line 232c connected to the cooling fluid storage 232a may extend into the lower cover 250 through the interior space 255 of the connecting member 253.

A plate 270 may be located between the electrostatic chuck 210 and the lower cover 250. The plate 270 may cover an upper surface of the lower cover 250. The plate 270 may have a sectional area corresponding to the body 230. The plate 270 may comprise an insulator. According to an embodiment, one or more plates 270 may be provided. The plate 270 may function to increase an electrical distance between the body 230 and the lower cover 250.

The shower head 300 may be located above the substrate support assembly 200 in the interior of the chamber 620. The shower head 300 may be located to face the substrate support assembly 200.

The shower head 300 may comprise a gas dispersing plate 310 and a support 330. The gas dispersing plate 310 may be spaced downwards apart from an upper surface of the chamber 620. A space may be formed between the gas dispersing plate 310 and the upper surface of the chamber 620. The gas dispersing plate 310 may have a plate shape having a specific thickness. The bottom surface of the gas dispersing plate 310 may be anodized to prevent generation of an arc by plasma. The gas dispersing plate 310 may have the same shape and cross-section as those of the substrate support assembly 200. The gas dispersing plate 310 may comprise a plurality of ejection holes 311. The ejection holes 311 may vertically pass through the upper surface and the lower surface of the gas dispersing plate 310. The gas dispersing plate 310 may comprise a metallic material.

The support 330 may support a side of the gas dispersing plate 310. An upper end of the support 330 may be connected to the upper surface of the chamber 620, and a lower end of the support 330 may be connected to a side of the gas dispersing plate 310. The support 330 may comprise a nonmetallic material.

The gas supply unit 400 may supply a process gas into the interior of the chamber 620. The gas supply unit 400 may comprise a gas supply nozzle 410, a gas supply line 420, and a gas storage unit 430. The gas supply nozzle 410 may be installed at a central portion of the upper surface of the chamber 620. An ejection hole may be formed on the bottom surface of the gas supply nozzle 410. A process gas may be supplied into the interior of the chamber 620 through the ejection hole. The gas supply unit 400 may connect the gas supply nozzle 410 and the gas storage unit 430. The gas supply line 420 may supply the process gas stored in the gas storage unit 430 to the gas supply nozzle 410. A valve 421 may be installed in the gas supply line 420. The valve 421 may open and close the gas supply line 420, and may adjust a flow rate of the process gas supplied through the gas supply line 420.

The baffle unit 500 may be located between the inner wall of the chamber 620 and the substrate support assembly 200. The baffle 510 may have an annular ring shape. The baffle 510 may have a plurality of through-holes 511. The process gas provided into the chamber 620 may pass through through-holes 511 of the baffle 510 to be exhausted through an exhaust hole 102. The flow of the process gas may be controlled according to the shape of the baffle 510 and the shape of the through-holes 511.

The plasma generating unit 600 may excite a process gas in the chamber 620 into a plasma state. According to an embodiment of the inventive concept, the plasma generating unit 600 may be of an inductively coupled plasma (ICP) type. In this case, as illustrated in FIG. 1, the plasma generating unit 600 may comprise a high frequency power source 610 configured to supply high frequency power, and a first coil 621 and a second coil 622 electrically connected to the high frequency power source 610 to receive high frequency power.

Although it has been described in the specification that the plasma generating unit 600 is of an inductively coupled plasma (ICP) type, the inventive concept is not limited thereto but the plasma generating unit 600 may be of a capacitively coupled plasma (CCP) type.

When the plasma source of a CCP type is used, an upper electrode and a lower electrode, that is, the body may be included in the chamber 620. The upper electrode and the lower electrode may be vertically disposed in parallel to each other while a treatment space is interposed therebetween. The upper electrode as well as the lower electrode may receive RF signals from an RF power source to receive energy for generating plasma, and the number of RF signals applied to the electrodes is not limited to one as illustrated. An electromagnetic field may be formed in a space between the two electrodes, and the process gas supplied into the space may be excited into a plasma state. A substrate treating process is performed by using the plasma.

Referring to FIG. 1 again, the first coil 621 and the second coil 622 may be disposed at locations that face the substrate W. For example, the first coil 621 and the second coil 622 may be installed above the chamber 620. The diameter of the first coil 621 may be smaller than the diameter of the second coil 622 such that the first coil 621 is located inside the upper side of the chamber 610 and the second coil 622 is located outside the upper side of the chamber 610. The first coil 621 and the second coil 622 may receive high frequency power from the high frequency power source 610 to induce a time-variable magnetic field in the chamber, and accordingly, the process gas supplied to the chamber may be excited by plasma.

Hereinafter, a process of treating a substrate by using the above-described substrate treating apparatus will be described.

If the substrate W is positioned on the substrate support assembly 200, a direct current may be applied from the first power source 223a to the first electrode 223. An electrostatic force may be applied between the first electrode 223 and the substrate W by a direct current applied to the first electrode 223, and the substrate W may be suctioned to the electrostatic chuck 210 by an electrostatic force.

If the substrate W is suctioned by the electrostatic chuck 210, the process gas may be supplied into the interior of the chamber 620 through the gas supply nozzle 410. The process gas may be uniformly ejected to an inner area of the chamber 620 through the ejection holes 311 of the shower head 300. The high frequency power generated by the high frequency power source may be applied to a plasma source, and accordingly, an electromagnetic force may be generated in the chamber 620. The electromagnetic force may excite the process gas between the substrate support assembly 200 and the shower head 300 by using plasma. The plasma is provided to the substrate W to treat the substrate W. The plasma may perform an etching process.

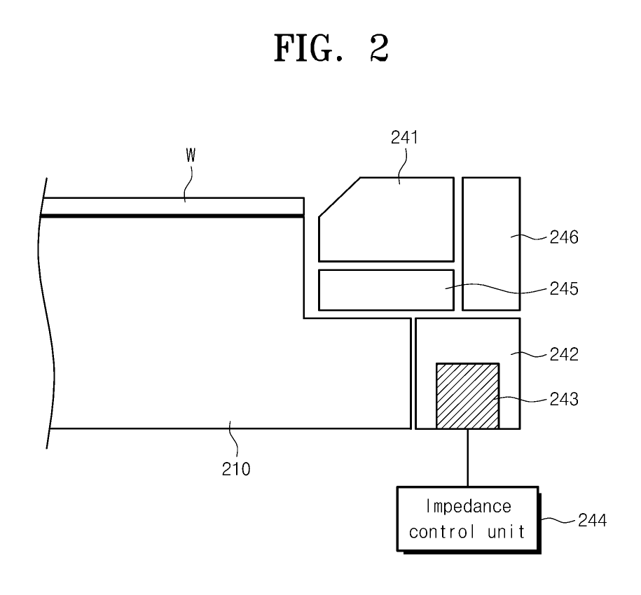

FIG. 2 is an exemplary sectional view of a portion of a substrate support unit according to an embodiment of the inventive concept.

As illustrated in FIG. 2, the substrate support unit according to an embodiment of the inventive concept may comprise an electrostatic chuck 210 and a ring member surrounding a circumference of the electrostatic chuck 210. As illustrated in FIG. 2, the substrate support unit may comprise an electrostatic chuck 210, a first ring 241, a second ring 242, an insertion body 243, and an impedance control unit 244.

As mentioned above, the substrate W may be positioned on the electrostatic chuck 210.

The first ring 241 may be provided to surround a circumference of the substrate positioned on the electrostatic chuck. According to an embodiment, the first ring 241 may be a focus ring. The focus ring may focus ions generated during the plasma process onto the substrate.

The second ring 242 may surround a circumference of the electrostatic chuck. According to an embodiment, the second ring 242 may be formed of an insulation material. The second ring 242 separates the electrostatic chuck and an outer wall of the chamber, and may electrically insulate the first ring 241 from the modules on the lower side of the electrostatic chuck.

According to an embodiment, a third ring 245 of a metallic material may be provided between the first ring 241 and the second ring 242. As an example, the third ring 245 may be formed of an aluminum material.

As illustrated in FIG. 2, according to an embodiment, a fourth ring 246 surrounding the circumferences of the first ring 241 and the third ring 245 may be further provided. The fourth ring 246 may be formed of an insulator.

According to an embodiment of the inventive concept, an insertion body 243 formed of a conductive material may be provided in the interior of the second ring 242. The insertion body 243 may be connected to the impedance control unit 244.

In an embodiment, the insertion body may be formed of a dielectric material. In an embodiment, the insertion body may be formed of a metallic material. In this way, because the insertion body formed of a conductive material, such as a dielectric material or a metallic material, is provided in the interior of the second ring 242, an electric field coupling effect may be induced around the second ring 242.

An RF power coupling degree between the electrostatic chuck 210 and the first ring 241 may be adjusted through the impedance control unit 244. Accordingly, the substrate support unit according to the embodiment of the inventive concept may easily control an electric field and a plasma density at a periphery of the electrostatic chuck.

Directions of ions input through the plasma sheath formed on the upper side of the first ring 241 may be controlled by controlling an electric field at a periphery of the electrostatic chuck. Accordingly, a degree, by which the upper side of the first ring 241 is worn, may be reduced.

Referring to FIG. 2, according to an embodiment, the second ring 242 may be disposed below the first ring 241. An upper end of a central area of the electrostatic chuck 210 may be higher than an upper end of a peripheral area of the electrostatic chuck 210. An upper end of the first ring 241 may be higher than an upper end of a central area of the electrostatic chuck 210. A lower end of the first ring 241 may be lower than the upper end of the central area. A portion of the first ring 241 may be located above a peripheral area of the electrostatic chuck 210. An upper end of the second ring 242 may be located at a height that is the same as or lower than an upper end of a peripheral area of the electrostatic chuck 210.

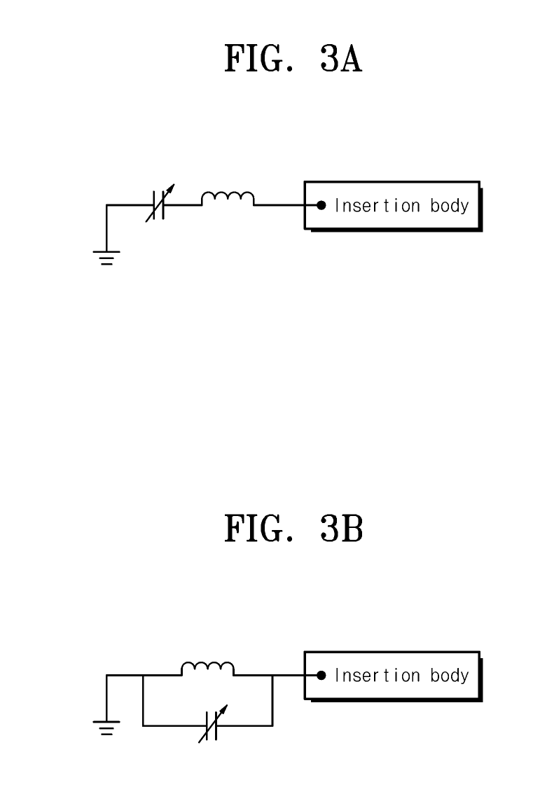

FIGS. 3A and 3B are exemplary circuit diagram of a circuit included in an impedance control unit of FIG. 2.

As illustrated in FIGS. 3A and 3B, the impedance control unit 244 may comprise a variable capacitor and an inductor. According to an embodiment, the variable capacitor and the inductor may be connected to each other in series or in parallel. However, a configuration of a circuit, by which the impedance control unit 244 may be realized, is not limited thereto, but any circuit having a configuration that may be electrically connected to the insertion body 243 to control high frequency power coupled to a periphery of an electrostatic chuck may be provided.

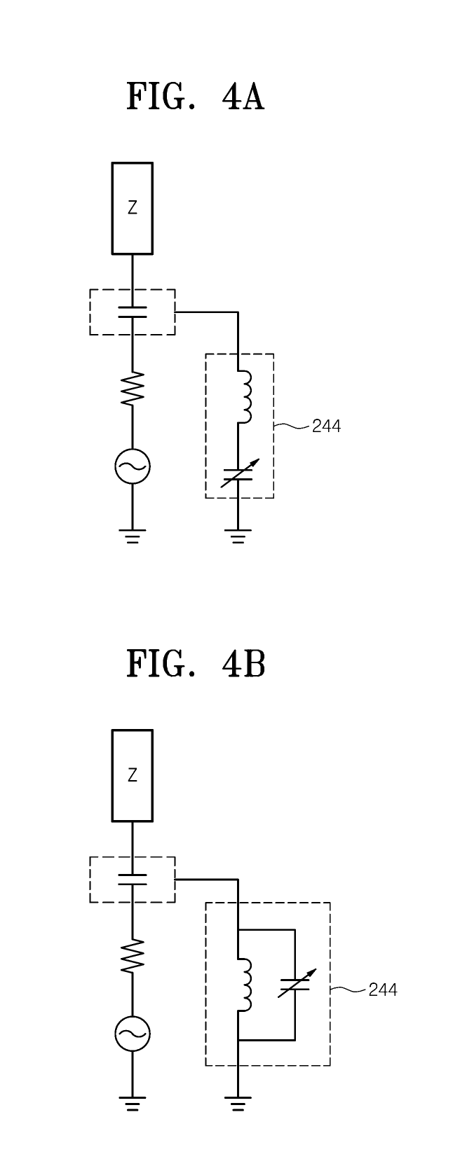

FIGS. 4A and 4B are exemplary circuit diagrams for explaining an operation of an impedance control unit according to an embodiment of the inventive concept.

As illustrated in FIGS. 4A and 4B, the impedance control unit 244 may adjust coupling between a plasma impedance Z and a high frequency power source configured to provide RF power to an electrode provided in the electrostatic chuck.

A potential of the plasma sheath formed at a periphery of the electrostatic chuck may be changed by changing the impedance of the second ring 242 through the impedance control unit 244. Accordingly, the ions input through the plasma sheath may be controlled. Accordingly, the substrate support unit according to an embodiment of the inventive concept may reinforce an etching rate of a periphery of a substrate and a function of controlling an etching profile.

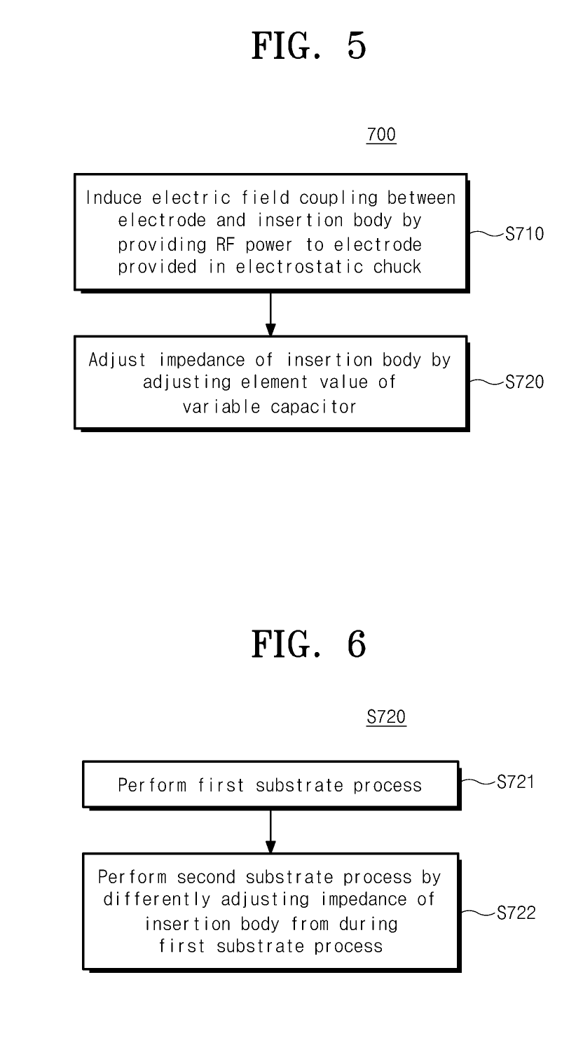

FIG. 5 is an exemplary flowchart illustrating a method for controlling a substrate treating apparatus according to an embodiment of the inventive concept.

Referring to FIG. 5, the method 700 for controlling a substrate treating apparatus according to an embodiment of the inventive concept may comprise an operation S710 of generating coupling between the electrode and the insertion body by providing RF power to an electrode provided in the electrostatic chuck, and an operation S720 of controlling an impedance of the insertion body by adjusting an element value of the variable capacitor.

Referring to FIG. 6, the operation S720 for controlling an impedance of the insertion body may comprise an operation S721 of treating a first substrate, and an operation S722 of treating a second substrate by adjusting the impedance of the insertion body differently as compared with when the first substrate is treated.

That is, the impedance control unit 244 may differently control the impedance of the insertion body during the treatment of the first substrate and the impedance of the insertion body during the treatment of the second substrate. However, the inventive concept is not limited thereto, but the impedance may be constantly maintained according to the process and the wearing degree of the focus ring.

According to an embodiment of the inventive concept, an electric field of a periphery of a substrate in a substrate treating apparatus that performs a plasma process may be easily controlled.

According to an embodiment of the inventive concept, an exchange cycle may be extended by reducing a degree by which a ring member provided at a circumference of a substrate support is worn.

According to an embodiment of the inventive concept, the uniformity of plasma formed in a peripheral area of a substrate may be increased by controlling an impedance of an insertion body inserted into a ring member.

The effects of the inventive concept are not limited to the above-mentioned effects, and the unmentioned effects can be clearly understood by those skilled in the art to which the inventive concept pertains from the specification and the accompanying drawings.

It is noted that the above embodiments are suggested for understanding of the inventive concept and do not limit the scope of the inventive concept, and various modifiable embodiments also fall within the scope of the inventive concept. For example, the elements illustrated in the embodiments of the inventive concept may be individually implemented, and some of the individual elements may be coupled to each other to be implemented. It should be understood that the technical protection range of the inventive concept has to be determined by the technical spirit of the claims, and the technical protection range of the inventive concept is not limited to the lexical meaning of the claims but reaches even to the equivalent inventions.

What is claimed is:

1. A substrate treating apparatus comprising:
a chamber having a treatment space in the interior thereof;
a support unit that supports a substrate in the treatment space;
a gas supply unit configured to supply a treatment gas into the treatment space; and
a plasma source configured to generate plasma from the treatment gas,
wherein the support unit comprises:
an electrostatic chuck, on which the substrate is positioned;
a first ring surrounding a circumference of the substrate positioned on the electrostatic chuck;
a second ring surrounding a circumference of the electrostatic chuck and formed of an insulation material;
an insertion body disposed in the second ring and formed of a conductive material; and
an impedance control unit configured to adjust an impedance of the insertion body.

2. The substrate treating apparatus of claim 1, wherein
the support unit further comprises:
a high frequency power source configured to provide RF power to an electrode provided in the electrostatic chuck, and
wherein the impedance control unit controls coupling between the electrostatic chuck and the first ring by adjusting an impedance of the insertion body.

3. The substrate treating apparatus of claim 2, wherein the impedance control unit comprises an inductor and a variable capacitor.

4. The substrate treating apparatus of claim 3, wherein the inductor and the variable capacitor are connected to each other in series or in parallel.

5. The substrate treating apparatus of claim 1, wherein the insertion body is formed of a metallic material.

6. The substrate treating apparatus of claim 1, wherein the insertion body is formed of a dielectric material.

7. The substrate treating apparatus of claim 1, wherein the second ring is disposed below the first ring.

8. The substrate treating apparatus of claim 1, wherein an upper end of a central area of the electrostatic chuck is higher than an upper end of a peripheral area of the electrostatic chuck.

9. The substrate treating apparatus of claim 8, wherein an upper end of the first ring is higher than the upper end of the central area of the electrostatic chuck, a lower end of the first ring is lower than the upper end of the central area, and a portion of the first ring is located above the peripheral area of the electrostatic chuck.

10. The substrate treating apparatus of claim 8, wherein an upper end of the second ring is located at a height that is the same as or lower than the upper end of the peripheral area of the electrostatic chuck.

11. The substrate treating apparatus of claim 1, wherein a third ring of a metallic material is provided between the first ring and the second ring.

12. A substrate support unit for supporting a substrate in a plasma process chamber, the substrate support unit comprising:
an electrostatic chuck, on which the substrate is positioned;
a first ring surrounding a circumference of the substrate positioned on the electrostatic chuck;
a second ring surrounding a circumference of the electrostatic chuck and formed of an insulation material;
an insertion body disposed in the second ring and formed of a conductive material; and
an impedance control unit configured to adjust an impedance of the insertion body.

13. The substrate support unit of claim 12, further comprising:
a high frequency power source configured to provide RF power to an electrode provided in the electrostatic chuck, and
wherein the impedance control unit controls coupling between the electrostatic chuck and the first ring by adjusting an impedance of the insertion body.

14. The substrate support unit of claim 13, wherein the impedance control unit comprises an inductor and a variable capacitor.

15. The substrate support unit of claim 14, wherein the inductor and the variable capacitor are connected to each other in series or in parallel.

16. The substrate support unit of claim 12, wherein the insertion body is formed of a metallic material.

17. The substrate support unit of claim 12, wherein the insertion body is formed of a metallic material.

18. The substrate support unit of claim 12, wherein the second ring is disposed below the first ring.

19. The substrate support unit of claim 12, wherein an upper end of a central area of the electrostatic chuck is higher than an upper end of a peripheral area of the electrostatic chuck.

20. The substrate support unit of claim 19, wherein an upper end of the first ring is higher than the upper end of the central area of the electrostatic chuck, a lower end of the first ring is lower than the upper end of the central area, and a portion of the first ring is located above the peripheral area of the electrostatic chuck.

21. The substrate support unit of claim 19, wherein an upper end of the second ring is located at a height that is the same as or lower than the upper end of the peripheral area of the electrostatic chuck.

22. The substrate support unit of claim 12, wherein a third ring of a metallic material is provided between the first ring and the second ring.

23. A method for controlling the substrate treating apparatus claimed in claim 3, the method comprising:
generating coupling between an electrode provided in the electrostatic chuck and the insertion body by providing RF power to the electrode; and
controlling an impedance of the insertion body by adjusting an element value of the variable capacitor.

24. The method of claim 23, wherein the controlling of the impedance of the insertion body comprises:
when a first substrate is treated and then a second substrate is treated, differently controlling an impedance of the insertion body during the treatment of the first substrate and an impedance of the insertion body during the treatment of the second substrate.
